(19) United States
(12) Patent Application Publication
(10) Pub. No.: US 2024/0324215 A1
(43) Pub. Date: Sep. 26, 2024

(54) SEMICONDUCTOR MEMORY DEVICE

(71) Applicant: Kioxia Corporation, Tokyo (JP)

(72) Inventors: Takashi KURUSU, Yokkaichi Mie (JP); Koji SHIRAI, Yokohama Kanagawa (JP)

(21) Appl. No.: 18/595,336

(22) Filed: Mar. 4, 2024

(30) Foreign Application Priority Data
Mar. 22, 2023 (JP) 2023-045243

(51) Int. Cl. H10B 43/27; H10B 43/35

(52) U.S. Cl. CPC H10B 43/27; H10B 43/35

(57) ABSTRACT

A semiconductor memory device includes a stacked body in which conductive layers and insulating layers are alternately stacked in a first direction, a columnar body in the stacked body and extending in the first direction, and a source line layer. The columnar body includes a core insulating layer, a semiconductor layer surrounding the core insulating layer, and a memory layer surrounding the semiconductor layer. A portion of the source line layer extends in the first direction to be provided in the stacked body, has a side surface in contact with the semiconductor layer and an end face in contact with the core insulating layer, and includes a pointed portion on the end face at an interface of the portion, the core insulating layer, and the semiconductor layer, wherein the end face and the side surface of the semiconductor layer form an acute angle at the pointed portion.

### CROSS-REFERENCE TO RELATED APPLICATION(S)

This application is based upon and claims the benefit of priority from Japanese Patent Application No. 2023-045243, filed Mar. 22, 2023, the entire contents of which are incorporated herein by reference.

### FIELD

Embodiments described herein relate generally to a semiconductor memory device.

### BACKGROUND

A semiconductor memory device including a stacked body in which a plurality of conductive layers and a plurality of insulating layers are stacked and a columnar body penetrating the stacked body is known.

### DESCRIPTION OF THE DRAWINGS

FIG. 1 is a block diagram showing a semiconductor memory device and a memory controller according to the first embodiment.

FIG. 2 is a diagram showing an equivalent circuit of a part of a memory cell array of the semiconductor memory device according to the first embodiment.

FIG. 3 is a sectional view showing a part of a semiconductor memory device according to a first embodiment.

FIG. 4 is a plan view showing a part of a semiconductor memory device according to a first embodiment.

FIG. 5 is a sectional view showing a columnar body of a semiconductor memory device according to a first embodiment.

FIG. 6 is an enlarged sectional view of a portion surrounded by a broken line in FIG. 3.

FIG. 7 is a sectional view showing a comparative example.

FIG. 8 is a diagram showing on-current characteristics of the semiconductor memory device according to the first embodiment.

FIG. 9 is a sectional view showing a core recess amount and a lens height.

FIG. 10 is a diagram showing off-current characteristics of the semiconductor memory device according to the first embodiment.

FIG. 11 is a diagram showing threshold voltage characteristics of the semiconductor memory device according to the first embodiment.

FIG. 12 is a diagram showing S factor characteristics of the semiconductor memory device according to the first embodiment.

FIGS. 13A to 13C are sectional views showing a method for manufacturing a source line layer and a core insulating layer according to the first embodiment.

FIGS. 14A and 14B are sectional views showing a modification example of the first embodiment.

FIG. 15 is a sectional view showing a part of a semiconductor memory device according to a second embodiment.

FIGS. 16A to 16D are sectional views showing the method for manufacturing the semiconductor memory device according to the second embodiment.

FIG. 17 is a diagram showing on-current characteristics of the semiconductor memory device according to the second embodiment.

FIG. 18 is a sectional view showing a recess amount.

FIG. 19 is a diagram showing off-current characteristics of the semiconductor memory device according to the second embodiment.

FIG. 20 is a diagram showing threshold voltage characteristics of the semiconductor memory device according to the second embodiment.

FIG. 21 is a diagram showing S factor characteristics of the semiconductor memory device according to the second embodiment.

FIG. 22 is a sectional view showing a modification example of the second embodiment.

FIG. 23 is a sectional view showing a part of a semiconductor memory device according to a third embodiment.

FIG. 24 is a diagram showing on-current characteristics of the semiconductor memory device according to the first embodiment and the semiconductor memory device according to the third embodiment.

### DETAILED DESCRIPTION

Embodiments provide a semiconductor memory device capable of improving electrical characteristics.

In general, according to one embodiment, a semiconductor memory device includes a stacked body in which a plurality of conductive layers and a plurality of insulating layers are alternately stacked in a first direction, a columnar body provided in the stacked body and extending in the first direction, and a source line layer containing a metal material. The columnar body includes a core insulating layer that extends in the first direction through the stacked body to be in contact with the source line layer, a semiconductor layer surrounding a side surface of the core insulating layer and in contact with the source line layer, and a memory layer surrounding a side surface of the semiconductor layer and in contact with the source line layer. A portion of the source line layer extends in the first direction to be provided in the stacked body, has a side surface in contact with a side surface of the semiconductor layer and an end face in the first direction in contact with the core insulating layer, and includes a pointed portion on the end face at an interface of the portion, the core insulating layer, and the semiconductor layer, wherein the end face of the portion and the side surface of the semiconductor layer form an acute angle at the pointed portion.

Hereinafter, the semiconductor memory device of the embodiment will be described with reference to the drawings.

In the following description, the same reference numerals will be given to configurations having the same or similar functions, and duplicate descriptions of the configurations will be omitted. In the present disclosure, the term “connection” is not limited to the case of being physically connected, but also includes the case of being electrically connected. In the present disclosure, “xx is provided on, above or below yy” is not limited to the case where xx is in contact with yy, but also includes the case where another member is interposed between xx and yy. In addition, in the present disclosure, “xx is provided on, above, or below yy” is an expression for convenience and does not specify the direction of gravity. In the present disclosure, the terms “parallel” and “orthogonal” also include when being “substantially parallel” and “substantially orthogonal”, respectively.

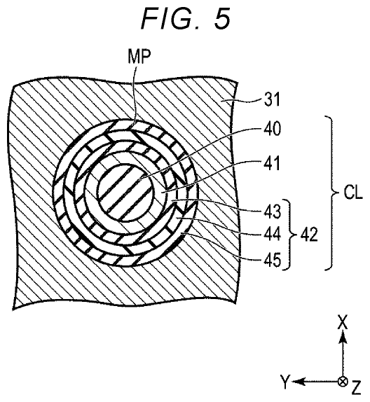

Next, an X direction, a Y direction, and a Z direction are defined. The X direction and the Y direction are directions substantially parallel to the surface of the substrate (the substrate 50 in FIG. 5) to be described later. The X direction and the Y direction intersect each other (for example, are orthogonal to each other). The Z direction intersects the X direction and the Y direction (for example, is orthogonal to the X direction and the Y direction), and is a direction away from the substrate. These expressions are for convenience only and do not specify the direction of gravity.

### First Embodiment

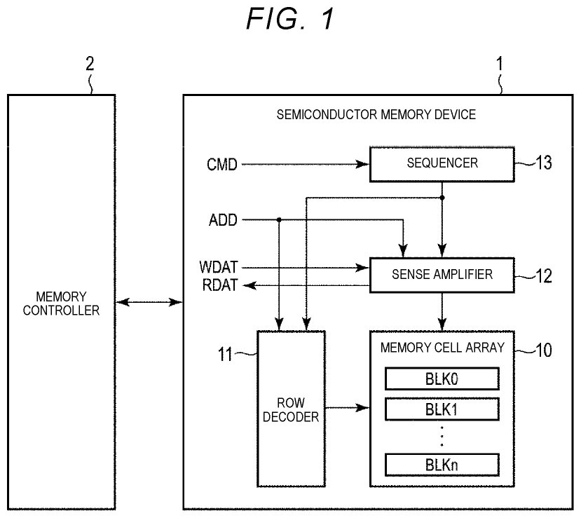

FIG. 1 is a block diagram showing a semiconductor memory device 1 and a memory controller 2 that controls the semiconductor memory device 1 according to the first embodiment.

The semiconductor memory device 1 is a non-volatile semiconductor memory device, and is, for example, a NAND flash memory. The semiconductor memory device 1 includes, for example, a memory cell array 10, a row decoder 11, a sense amplifier 12, and a sequencer 13.

The memory cell array 10 includes a plurality of blocks BLK0 to BLKn (n is an integer equal to or larger than 1). Hereinafter, when it is not necessary to distinguish between BLK0 to BLKn, BLK0 to BLKn are referred to as BLK. Each block BLK includes a plurality of non-volatile memory cell transistors. A plurality of bit lines and a plurality of word lines are provided in the memory cell array 10. Each memory cell transistor is connected to one bit line and one word line. A detailed configuration of the memory cell array 10 will be described below.

The row decoder 11 selects one block BLK based on the address information ADD received from the memory controller 2. The row decoder 11 controls a write operation and a read operation of data with respect to the memory cell array 10 by applying a desired voltage to each of the plurality of word lines.

The sense amplifier 12 applies a desired voltage to each bit line in response to the write data WDAT received from the memory controller 2. The sense amplifier 12 determines the data stored in the memory cell transistor based on the voltage of the bit line, and transmits the determined read data RDAT to the memory controller 2.

The sequencer 13 controls the operation of the entire semiconductor memory device 1 based on the command CMD received from the memory controller 2.

The semiconductor memory device 1 and the memory controller 2 described above may be combined to configure one semiconductor device, information processing device, or information processing system.

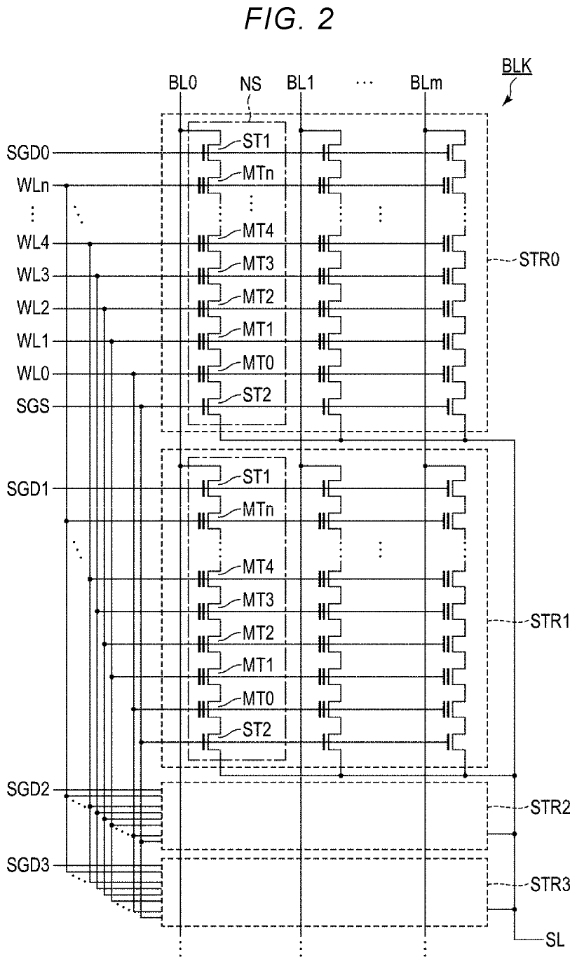

FIG. 2 is a diagram showing an equivalent circuit of a part of the memory cell array 10. FIG. 2 shows one extracted block BLK provided in the memory cell array 10. The block BLK includes a plurality of strings STR0 to STR3.

Each of the strings STR0 to STR3 is a collection of a plurality of NAND strings NS. One end of each NAND string NS is connected to any one of the bit lines BL0 to BLm (m is an integer of 1 or more). The other end of the NAND string NS is connected to the source line SL. Each NAND string NS includes a plurality of memory cell transistors MT0 to MTn (where n is an integer of 1 or more), a drain-side select transistor ST1, and a source-side select transistor ST2.

The plurality of memory cell transistors MT0 to MTn are connected in series. Each of the memory cell transistors MT0 to MTn includes a semiconductor layer in which a channel is formed and a memory layer (a tunnel insulating layer, a charge storage layer, and a block insulating layer), and stores data in a non-volatile manner. The memory cell transistor MT changes the state of the memory layer (for example, stores a charge in the charge storage layer) according to a voltage applied to the gate electrode. The gate electrode of the memory cell transistor MT is connected to one of the corresponding word lines WL0 to WLn. The memory cell transistor MT is connected to the row decoder 11 through the word line WL.

The drain-side select transistor ST1 in each NAND string NS is connected between the plurality of memory cell transistors MT0 to MTn and one of the bit lines BL0 to BLm. The drain of the drain-side select transistor ST1 is connected to one of the bit lines BL0 to BLm. The source of the drain-side select transistor ST1 is connected to the memory cell transistor MTn. The gate electrode of the drain-side select transistor ST1 in each of the NAND strings NS is connected to one of the select gate lines SGD0 to SGD3. The drain-side select transistor ST1 is connected to the row decoder 11 through one of the select gate lines SGD0 to SGD3. The drain-side select transistor ST1 connects the NAND string NS and the bit line BL to each other when a predetermined voltage is applied to a corresponding one of the select gate lines SGD0 to SGD3.

The source-side select transistor ST2 in each NAND string NS is connected between the plurality of memory cell transistors MT0 to MTn and the source line SL. The drain of the source-side select transistor ST2 is connected to the memory cell transistor MT0. A source of the source-side select transistor ST2 is connected to the source line SL. A gate electrode of the source-side select transistor ST2 is connected to a source-side select gate line SGS. The source-side select transistor ST2 is connected to the row decoder 11 through a source-side select gate line SGS. The source-side select transistor ST2 connects the NAND string NS to the source line SL when a predetermined voltage is applied to the source-side select gate line SGS.

The memory cell array 10 may have another circuit configuration other than the above-described circuit configuration. For example, the number of each string STR provided in each block BLK, the numbers of memory cell transistors MT and select transistors ST1 and ST2 provided in each NAND string NS may be changed. In addition, the NAND string NS may include one or more dummy cell transistors. The dummy cell transistor has the same structure as the memory cell transistors MT0 to MTn, but is not used for storing data.

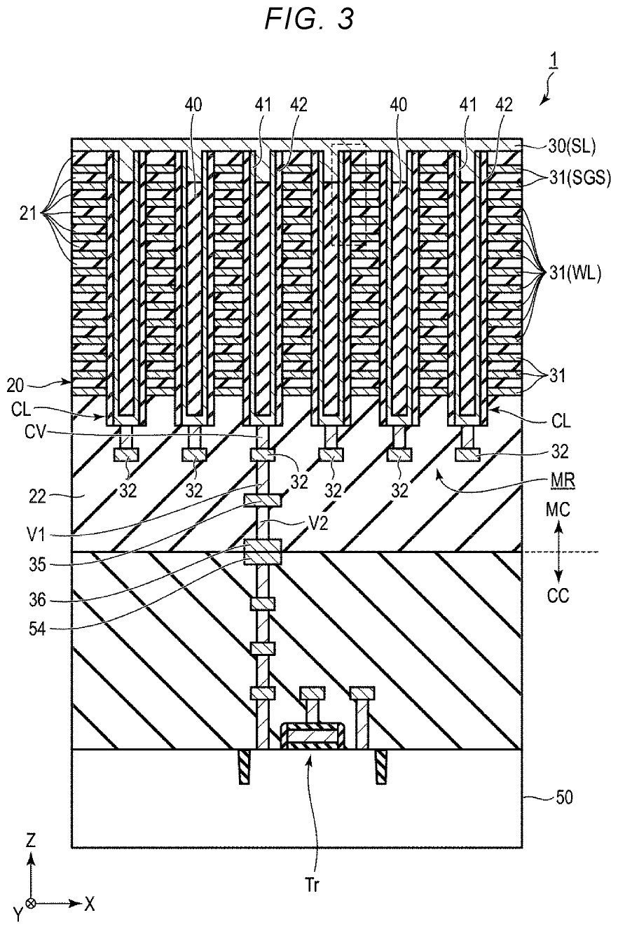

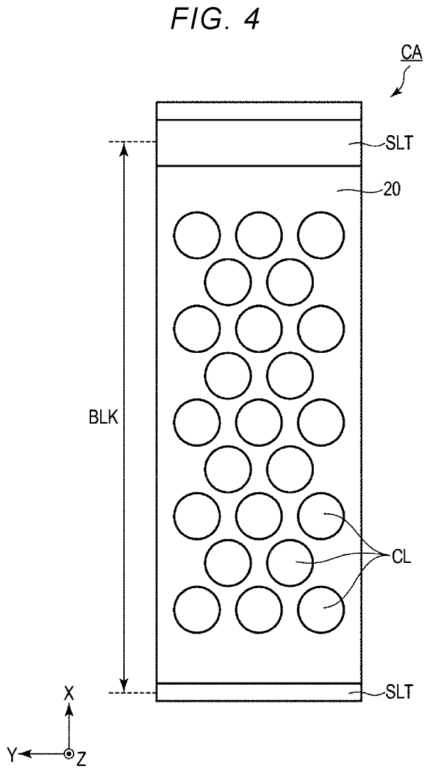

FIG. 3 is a sectional view showing a part of the semiconductor memory device 1. FIG. 4 is a plan view showing a part of the semiconductor memory device 1.

The semiconductor memory device 1 includes one or more memory chips and circuit chips respectively bonded together, and FIG. 3 shows one memory chip MC and one circuit chip CC. The memory chip MC and the circuit chip CC are bonded to each other. FIG. 3 shows a structure in which a lower surface of the memory chip MC and an upper surface of the circuit chip CC are bonded to each other.

The memory chip MC includes a structure corresponding to the memory cell array 10. Specifically, the memory region MR of the memory chip MC includes the stacked body 20, the plurality of columnar bodies CL, the source line layer 30, the insulating layer 22, the plurality of bit line layers 32, the pads 35 and 36, the contact V1, and the contact V2. The memory region MR is a region in which a plurality of memory cell transistors MT in FIG. 2 are three-dimensionally arranged.

As shown in FIG. 4, the memory region MR is partitioned into blocks BLK by the partition portion SLT. A region partitioned by the partition portion SLT corresponds to the one block BLK. The plurality of columnar bodies CL correspond to the NAND strings NS in FIG. 2. The plurality of columnar bodies CL are scattered in the memory region MR in a plan view from the Z direction. The plurality of columnar bodies CL are arranged in a zigzag shape in the Y direction in a plan view from the Z direction, for example. The columnar body CL has, for example, a circular shape or an elliptical shape in a plan view from the Z direction.

As shown in FIG. 3, the stacked body 20 includes a plurality of insulating layers 21 and a plurality of conductive layers 31. The plurality of insulating layers 21 and the plurality of conductive layers 31 are alternately stacked one by one in the Z direction.

Each insulating layer 21 extends in the X direction and the Y direction. The insulating layer 21 contains, for example, silicon oxide. The insulating layer 21 is provided between the conductive layer 31 and the source line layer 30 and between the conductive layers 31 adjacent to each other in the Z direction. The insulating layer 21 insulates the two conductive layers 31 adjacent to each other in the Z direction. In FIG. 3, the insulating layer 21 between the conductive layer 31 and the source line layer 30 is thicker than the insulating layer 21 between the two conductive layers 31 adjacent to each other in the Z direction.

Each conductive layer 31 extends in the X direction and the Y direction. Among the plurality of conductive layers 31, at least one from and including the uppermost conductive layer 31 in the stacked body 20 is used as a gate electrode of a source-side select transistor. Among the plurality of conductive layers 31, at least one from and including the lowermost conductive layer 31 in the stacked body 20 is used as a gate electrode of a drain-side select transistor. Among the plurality of conductive layers 31, the conductive layers 31 other than the ones used as the source-side select transistor and the drain-side select transistor are used as the gate electrodes of the memory cell transistors. Each conductive layer 31 used as a gate electrode of a memory cell transistor surrounds, for example, a side surface (outer periphery) of a columnar body CL. The plurality of conductive layers 31 may include one or more conductive layers used as gate electrodes of one or more dummy memory cell transistors.

The insulating layer 22 is provided below the lowermost conductive layer 31. The bit line layer 32 is provided in the insulating layer 22. The bit line layer 32 is a metal wiring layer corresponding to the bit lines BL in FIG. 2. The source line layer 30 is provided on the stacked body 20. The source line layer 30 is a metal wiring layer corresponding to the source line SL in FIG. 2. The source line layer 30 is connected to the plurality of columnar bodies CL. As the material of the source line layer 30 and the bit line layer 32, a metal material such as titanium, titanium nitride, nickel, aluminum, tungsten, or metal silicide (for example, titanium silicide) is used.

The bit line layer 32 and the contacts CV are provided in the insulating layer 22. The bit line layer 32 is disposed below the columnar body CL. Each contact CV is disposed between a columnar body CL and the bit line layer 32. Each columnar body CL and the bit line layer 32 are connected to each other via a contact CV. In a region not shown in FIG. 3, there are other plurality of columnar bodies CL that are connected to other plurality of contacts, respectively. The bit line layer 32 is connected to the circuit chip CC via the contact V1, the conductive layer 35, the contact V2, the pad 36, and the like.

FIG. 5 is a sectional view showing a columnar body CL of a semiconductor memory device 1 according to a first embodiment.

The columnar body CL includes the core insulating layer 40, the semiconductor layer 41, and the memory layer 42. The core insulating layer 40 has a columnar shape. The semiconductor layer 41 and the memory layer 42 have a cylindrical shape.

The core insulating layer 40 extends in the Z direction. The core insulating layer 40 is formed of, for example, a silicon oxide. The semiconductor layer 41 extends in the Z direction. The semiconductor layer 41 surrounds the side surface of the core insulating layer 40. The semiconductor layer 41 is formed of, for example, silicon. A channel of a drain-side select transistor, a memory cell transistor, or a source-side select transistor ST2 is formed in the semiconductor layer 41. Since the material of the source line layer 30 is a metal material, a Schottky junction is formed at the contact portion between the semiconductor layer 41 and the source line layer 30.

The memory layer 42 extends in the Z direction. The memory layer 42 surrounds the side surface of the semiconductor layer 41. The memory layer 42 includes a tunnel insulating layer 43, a charge storage layer 44, and a block insulating layer 45. These films are provided in the order of the tunnel insulating layer 43, the charge storage layer 44, and the block insulating layer 45 from the semiconductor layer 41 side.

The tunnel insulating layer 43 surrounds the side surface of the semiconductor layer 41. The tunnel insulating layer 43 is formed of, for example, a silicon oxide. The charge storage layer 44 surrounds the side surface of the tunnel insulating layer 43. The charge storage layer 44 contains, for example, silicon nitride. The block insulating layer 45 surrounds the side surface of the charge storage layer 44. The block insulating layer 45 is formed of, for example, a silicon oxide.

Referring again to FIG. 3, the circuit chip CC includes a control circuit (shown in the figure) for controlling the operation of the memory chip MC. The circuit chip CC includes a substrate 50, a transistor Tr, and a second pad 54 provided above the transistor Tr. Although only one transistor Tr is shown in FIG. 3, in practice, a plurality of transistors constituting the control circuit are present. In addition, in FIG. 3, for the sake of simplicity, reference numerals are not given to the contacts and the conductive layers connected to the second pad 54.

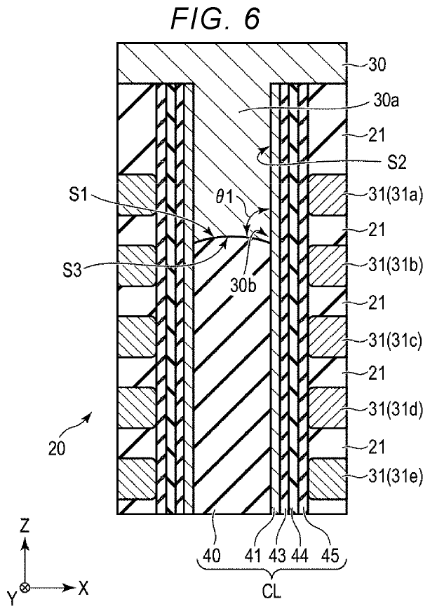

FIG. 6 is an enlarged sectional view of a portion surrounded by a broken line in FIG. 3.

FIG. 6 shows five conductive layers 31 (31a, 31b, 31c, 31d, 31e). The two uppermost conductive layers 31a and 31b in the stacked body 20 constitute the gate electrodes of two source-side select transistors. The three conductive layers 31c, 31d, and 31e below the conductive layer 31b constitute the gate electrodes of three memory cell transistors. A conductive film such as a barrier film (not shown) may be provided on the surfaces of the conductive layers 31a, 31b, 31c, 31d, and 31e.

The source line layer 30 is connected to the columnar body CL. A portion 30a of the source line layer 30 is provided in the stacked body 20. A portion 30a of the source line layer 30 is connected to the columnar body CL. Specifically, a portion 30a of the source line layer 30 is connected to the columnar body CL by being in contact with the upper surface S1 of the core insulating layer 40 and the side surface S2 of the semiconductor layer 41. Hereinafter, a portion 30a of the source line layer 30 is referred to as a source line connection portion 30a.

The source line connection portion 30a includes a pointed portion 30b that includes the lower surface S3 of the source line connection portion 30a and a side surface of the source line connection portion 30a that is in contact with the side surface S2 of the semiconductor layer 41, and forms an acute angle between the two surfaces. The pointed portion 30b is formed at a place where the upper surface S1 of the core insulating layer 40, the side surface S2 of the semiconductor layer 41, and the lower surface S3 of the source line connection portion 30a are in contact with each other. In the present embodiment, the pointed portion 30b of the source line layer 30 is disposed between the conductive layer 31b and the conductive layer 31c in the Z direction.

The upper surface S1 of the core insulating layer 40 is a curved surface that is convex (convex surface facing the +Z direction) and has a positive curvature. The lower surface S3 of the source line connection portion 30a is a curved surface that is concave (concave surface facing the −Z direction) and has a negative curvature. The angle θ1 of the pointed portion 30b is less than 90 degrees, and the larger the curvature of the upper surface S1 of the core insulating layer 40, the smaller the angle θ1.

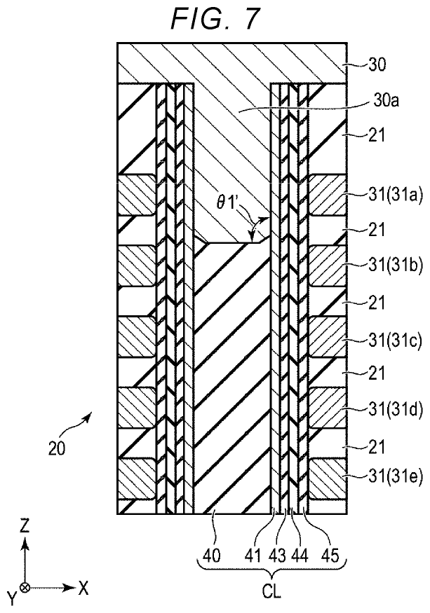

FIG. 7 is a sectional view showing a comparative example. In the comparative example, since the lower surface of the source line connection portion 30a is a surface that is convex, the angle θ1′ corresponding to the angle θ1 is larger than 90 degrees (θ1′ is larger than 01). Therefore, when the present embodiment is compared with the comparative example, the electric field concentration at the place where the upper surface S1, the side surface S2, and the lower surface S3 are in contact with each other is higher in the present embodiment than in the comparative example. Since the pointed portion 30b of the source line connection portion 30a is located on the lateral side (X direction side) of the conductive layer 31a and the conductive layer 31b, the on-current and the S factor of the source-side select transistor are improved.

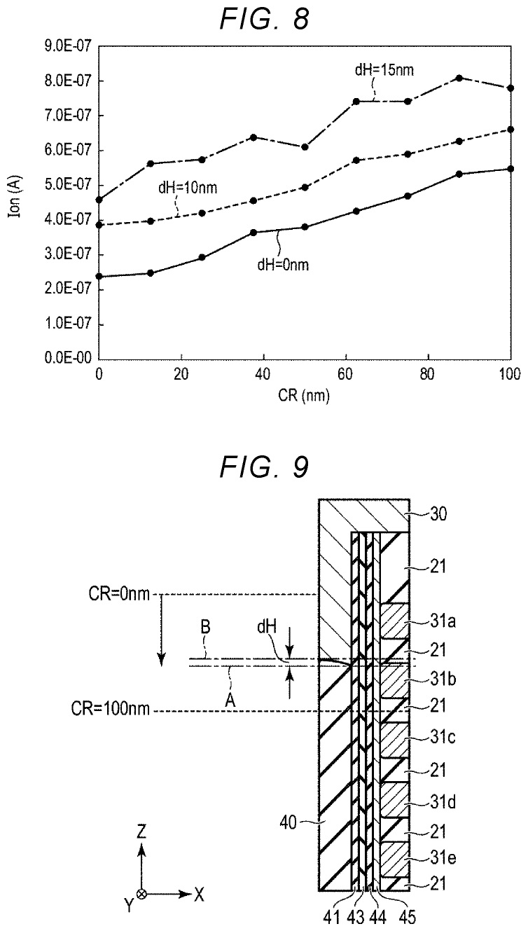

FIG. 8 is a diagram showing the on-current characteristics of the semiconductor memory device of the present embodiment, and more specifically, shows the relationship between the on-current, the core recess amount, and the lens height of the source-side select transistor of the present embodiment. In FIG. 8, the on-current is indicated by Ion, the core recess amount is indicated by CR, and the lens height is indicated by dH.

FIG. 9 is a sectional view showing a core recess amount CR and a lens height dH. CR=0 nm indicates a position away from a center position of the conductive layer 31a in the Z direction by one-half pitch between the conductive layers 31a and 31b. CR=100 nm is a position away from the position of CR=0 nm in the Z direction by twice the pitch between the conductive layers 31a and 31b. That is, CR=100 nm is a position that is midway between the conductive layer 31b and the conductive layer 31c in the Z direction. dH is a difference (B-A) between a position A of a place where the upper curved surface of the core insulating layer 40 is the lowest in the Z direction and a place B where the upper curved surface of the core insulating layer 40 is the highest in the Z direction. In the description herein, this difference, dH, is referred to as the “lens height.”

From FIG. 8, it can be seen that the larger the lens height dH (i.e., larger the curvature), the more the on-current Ion is improved. In addition, from FIG. 8, it can be seen that the larger the core recess amount CR, the larger the on-current Ion when the lens height dH is the same.

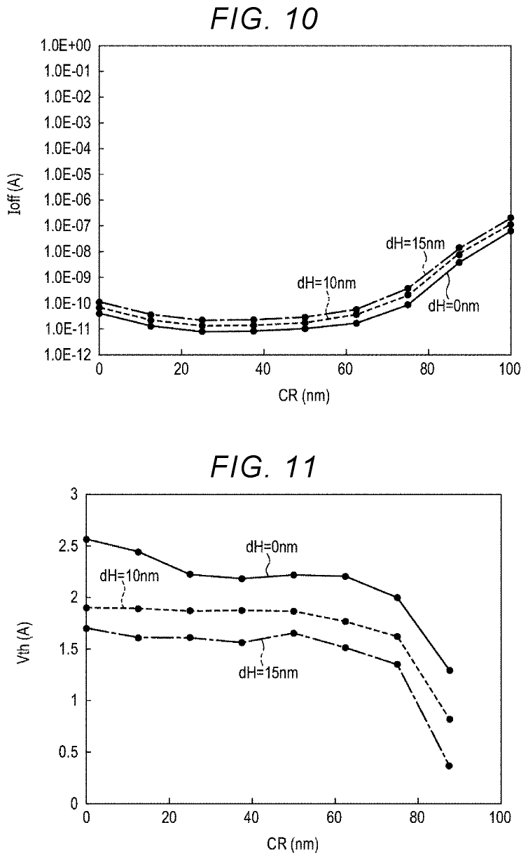

FIG. 10 is a diagram showing the off-current characteristics of the semiconductor memory device, and more specifically, shows the relationship between the off-current, the core recess amount, and the lens height of the source-side select transistor of the present embodiment. In FIG. 10, the off-current is indicated by Ioff. From FIG. 10, it can be seen that the influence of the lens height dH on the off-current Ioff is small.

FIG. 11 is a diagram showing the threshold voltage characteristics of the semiconductor memory device of the present embodiment, and more specifically, shows the relationship between the threshold voltage, the core recess amount, and the lens height of the source-side select transistor of the present embodiment. In FIG. 11, the threshold voltage is indicated by Vth. From FIG. 11, it can be seen that the larger the lens height dH, the lower the threshold voltage Vth. A low threshold voltage Vth leads to an increase in the driving power of the source-side select transistor.

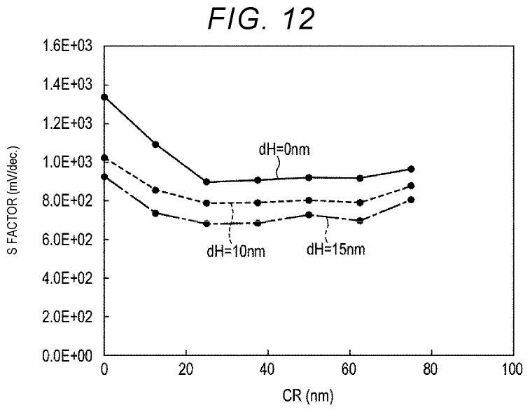

FIG. 12 is a diagram showing the S factor characteristics of the semiconductor memory device of the present embodiment, and more specifically, shows the relationship between the S factor, the core recess amount, and the lens height of the source-side select transistor of the present embodiment. From FIG. 12, it can be seen that the larger the lens height dH, the smaller the S factor. A small S factor leads to an increase in the driving power of the source-side select transistor.

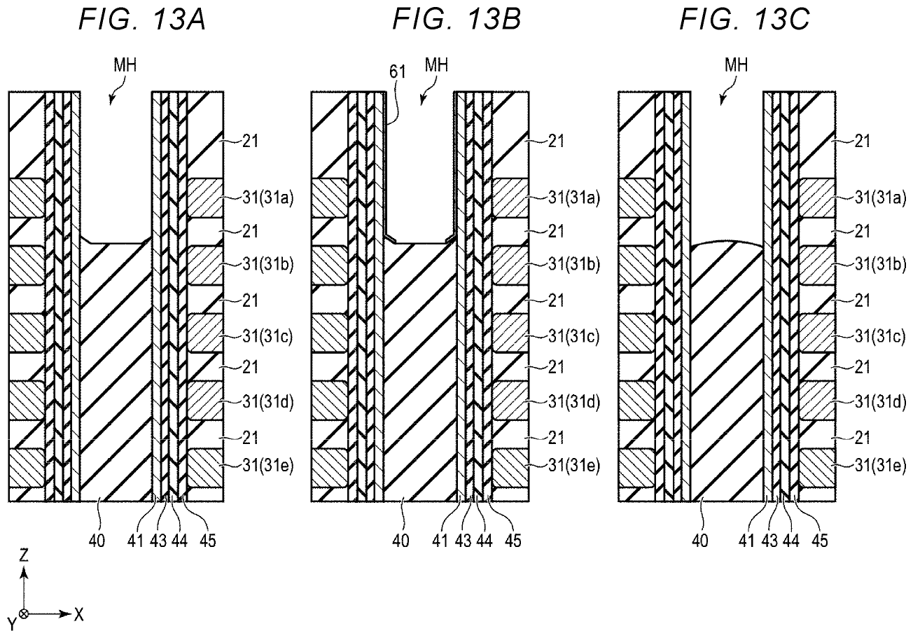

FIGS. 13A to 13C are sectional views showing a method for manufacturing a source line layer 30 and a core insulating layer 40 of the present embodiment. Here, a case when the core insulating layer 40 is a silicon oxide layer will be described.

FIG. 13A shows a sectional view in which the memory chip MC (not shown) and the circuit chip CC (not shown) are bonded and the core insulating layer 40 is embedded in the memory hole MH, and then the upper portion of the core insulating layer 40 is removed using wet etching. As a result of removing the upper portion of the core insulating layer 40, a part of the side surface of the semiconductor layer 41 is exposed. Since wet etching is used, the etching rate of the peripheral edge portion (the portion in contact with the semiconductor layer 41) of the upper surface of the core insulating layer 40 is low. As a result, the upper surface of the core insulating layer 40 is a curved surface that is concave.

FIG. 13B shows a sectional view in which the prevention layer 61 that prevents the formation of the silicon oxide in a partial region of the core insulating layer 40 and a partial region of the semiconductor layer 41 is formed. A partial region of the core insulating layer 40 is a peripheral edge portion of the upper surface of the core insulating layer 40. The partial region of the semiconductor layer 41 is a side surface of the exposed semiconductor layer 41.

FIG. 13C shows a sectional view in which the silicon oxide is formed on the upper surface of the core insulating layer 40. Since the silicon oxide is not formed at the peripheral edge portion of the upper surface of the core insulating layer 40, the upper surface of the core insulating layer 40 is a curved surface that is convex. When the source line layer 30 (not shown) is formed on the upper surface of the core insulating layer 40, the lower surface of the source line layer 30 is a curved surface that is concave.

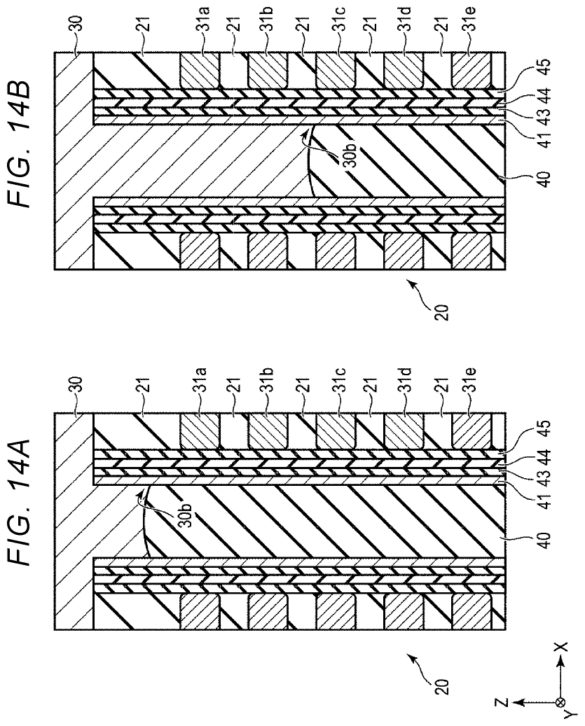

As described above, the pointed portion 30b of the source line layer 30 is disposed between the conductive layer 31b and the conductive layer 31c in the Z direction. However, as shown in FIG. 14A, the pointed portion 30b may also be disposed above the conductive layer 31ain the Z direction. In addition, as shown in FIG. 14B, the pointed portion 30b may also be disposed between the conductive layer 31b and the conductive layer 31c in the Z direction.

FIG. 14A and FIG. 14B depict two positions of the pointed portion 30b. The position of the pointed portion 30b is appropriately determined so that the electrical characteristics (on-current, threshold voltage, and S factor) can be improved by the pointed portion 30b.

### Second Embodiment

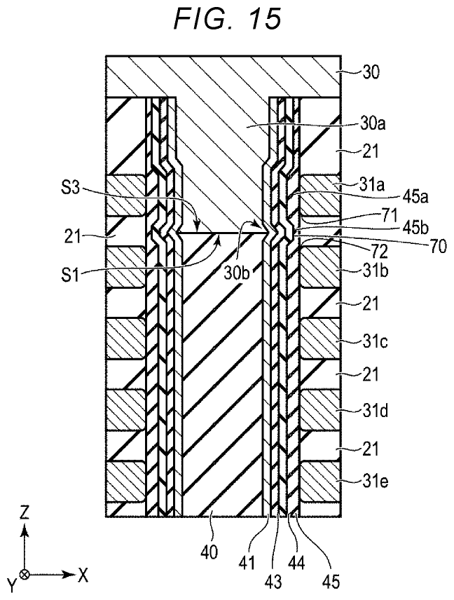

FIG. 15 is a sectional view showing a part of the semiconductor memory device according to the second embodiment, and corresponds to an enlarged sectional view of FIG. 5.

The present embodiment is different from the first embodiment in that the dimension of the block insulating layer 45 in the X direction is partially reduced. Specifically, the first dimension of the block insulating layer 45 (45b) in the X direction between the insulating layer 21 between two conductive layers 31a and 31b and the charge storage layer 44 is smaller than the second dimension of the block insulating layer 45 (45a) in the X direction between the conductive layer 31a and the charge storage layer 44.

The reason why the first dimension is smaller than the second dimension is that the semiconductor layer 41 and the memory layer 42 include a protruding portion protruding towards the insulating layer 21 side (X direction).

In FIG. 15, the protruding portion of the charge storage layer 44 of the memory layer 42 is denoted by the reference numeral 70. However, for the sake of simplicity, the protruding portion of the semiconductor layer 41 and the protruding portion of the tunnel insulating layer 43 configuring the memory layer 42 are not denoted by the reference numerals.

The protruding portion of the semiconductor layer 41 protrudes towards the insulating layer 21 side to burrow into the side surface of the tunnel insulating layer 43. The protruding portion of the tunnel insulating layer 43 protrudes towards the insulating layer 21 side to burrow into the side surface of the charge storage layer 44. The protruding portion of the charge storage layer 44 protrudes towards the insulating layer 21 side to burrow into the side surface of the block insulating layer 45.

By causing the protruding portion of the semiconductor layer 41, the protruding portion of the tunnel insulating layer 43, and the protruding portion 70 of the charge storage layer 44 to protrude towards the insulating layer 21 side in this way, the first dimension of the block insulating layer 45b in the X direction is reduced. The dimensions of the semiconductor layer 41, the tunnel insulating layer 43, and the charge storage layer 44 in the X direction are substantially uniform.

In addition, in the semiconductor memory device of the present embodiment, unlike the first embodiment, the lower surface of the source line layer 30 is flat, and the upper surface of the core insulating layer 40 is also flat. The protruding portion 70 is disposed adjacent to the pointed portion 30b in the X direction.

Meanwhile, the semiconductor layer 41 and the memory layer 42 of the memory cell transistor have a uniform dimension in the X direction and do not include a protruding portion.

Next, a structure in which the first dimension is smaller than the second dimension (hereinafter, referred to as a first structure) and a structure in which the first dimension is the same as the second dimension (hereinafter, referred to as a second structure) are compared.

The electric field generated at the corner portion 71 on the lower surface side of the conductive layer 31a when a voltage is applied to the word line is larger in the first structure than in the second structure. Similarly, the electric field at the corner portion 72 on the upper surface side of the conductive layer 31b is larger in the first structure than in the second structure. Therefore, when the first structure is used, the current flowing beyond the Schottky barrier is larger than when the second structure is used, and the current drive power of the source-side select transistor is larger.

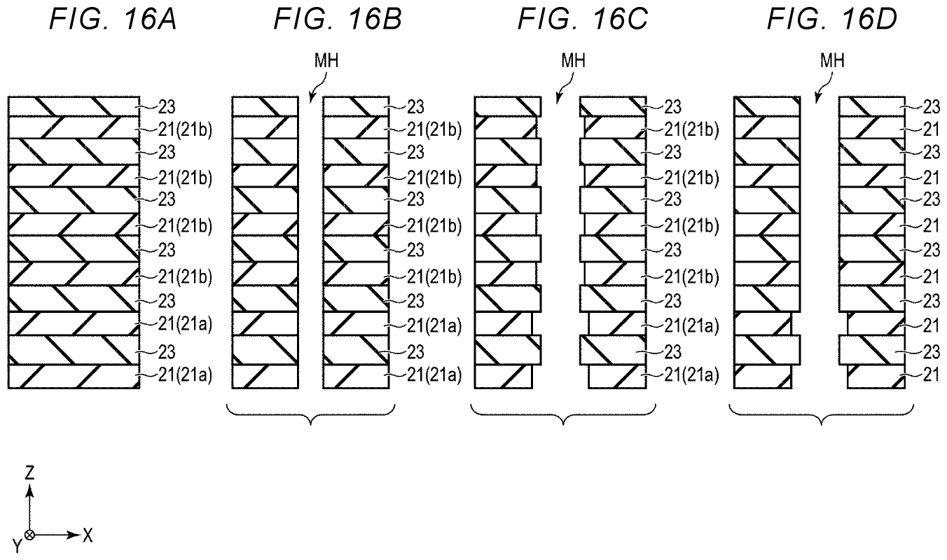

FIGS. 16A to 16D are sectional views showing a method for manufacturing the first structure.

FIG. 16A shows a structural insulating layer in which a plurality of insulating layers 21 (21a, 21b) and a plurality of insulating layers (sacrificial layers) 23 are alternately stacked one by one in the Z direction.

The insulating layer 21 (21a, 21b) contains an oxide-based insulating material such as silicon oxide as a main component. Meanwhile, the material of the insulating layer 21a and the material of the insulating layer 21b are selected such that the etching rate of the insulating layer 21a is higher than the etching rate of the insulating layer 21b when the insulating layer 21a and the insulating layer 21b are etched. Therefore, the etching rate of the insulating layer 21a in the region in which the select transistor is formed is higher than the etching rate of the insulating layer 21bin the region in which the memory cell transistor is formed.

FIG. 16B shows a stacked insulating layer in which the memory hole MH is formed by etching the plurality of insulating layers 21 and the plurality of insulating layers 23.

FIG. 16C shows a stacked insulating layer in which a plurality of insulating layers 21 (21a, 21b) are subjected to a recess processing (first recess processing) using etching to shorten the dimensions of the plurality of insulating layers 21 (21a, 21b) in the X direction.

Here, since the insulating layer 21a has a higher etching rate than the insulating layer 21b, the dimension of the insulating layer 21a in the X direction is shorter than the dimension of the insulating layer 21b in the X direction. In addition, the plurality of insulating layers 23 are hardly etched by the first recess processing. That is, the selective etching of the plurality of insulating layers 21 can be performed.

FIG. 16D shows a stacked structure in which a plurality of insulating layers 23 are subjected to a recess processing (second recess processing) using etching to shorten the dimensions of the plurality of insulating layers 23 in the X direction. Here, the second recess processing is performed such that the dimensions of the plurality of insulating layers 23 in the X direction are the same as the dimensions of the plurality of insulating layers 21 in the X direction. In addition, the plurality of insulating layers 21 are hardly etched by the second recess processing. That is, the selective etching of the plurality of insulating layers 23 can be performed.

Thereafter, a well-known process is performed, in which the block insulating layer 45, the charge storage layer 44, the tunnel insulating layer 43, the semiconductor layer 41, and the core insulating layer 40 are formed in the memory hole MH, a slit (groove) is formed in the stacked insulating layer, the insulating layer 23 is removed using etching, and the conductive layer 31 is formed in the region from which the insulating layer 23 is removed.

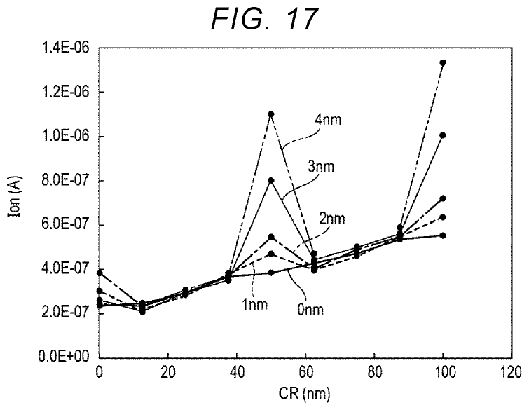

FIG. 17 is a diagram showing the on-current characteristics of the semiconductor memory device of the present embodiment, and more specifically, shows the relationship between the on-current, the core recess amount, and the block layer recess amount of the source-side select transistor of the present embodiment. In FIG. 17, the block layer recess amount is indicated by several lines.

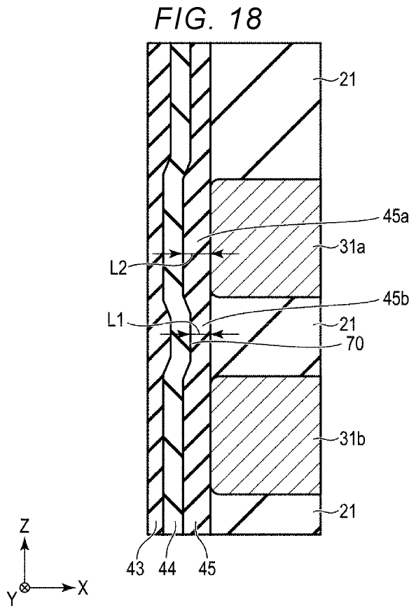

FIG. 18 is a sectional view showing a block layer recess amount. In FIG. 18, L1 and L2 indicate the above-described first dimension and second dimension, respectively. The block layer recess amount is defined by, for example, a difference (L2-L1) between the first dimension L1 and the second dimension L2. The first dimension L1 is, for example, a dimension of a portion of the block insulating layer 45b that has the smallest dimension in the X direction. In addition, the block layer recess amount is defined by the amount of reduction in the dimension of the insulating layer 21a in the X direction due to the etching of FIG. 16C.

From FIG. 17, it can be seen that when the core recess amount is 50 nm, the larger the block layer recess amount, the more the on-current is improved. The case when the core recess amount is 50 nm is a case where the interface between the source line layer 30 and the core insulating layer 40 is located at the center between the conductive layer 31a and the conductive layer 31b in the Z direction.

FIG. 19 is a diagram showing the off-current characteristics of the semiconductor memory device of the present embodiment, and more specifically, shows the relationship between the off-current, the core recess amount, and the block layer recess amount of the source-side select transistor of the present embodiment. From FIG. 19, it can be seen that the influence of the block layer recess amount on the off-current is small, and there is no noticeable deterioration in the off-current as long as the block layer recess amount is up to 3 nm.

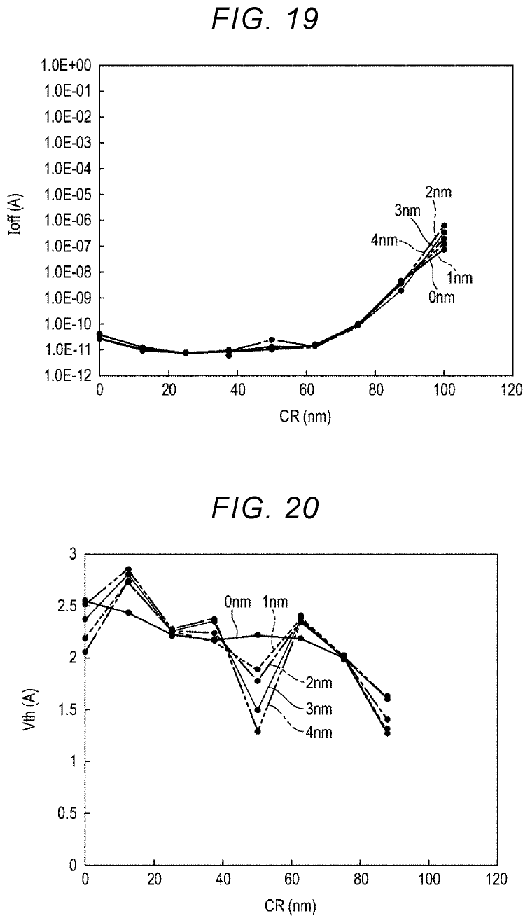

FIG. 20 is a diagram showing the threshold voltage characteristics of the semiconductor memory device of the present embodiment, and more specifically, shows the relationship between the threshold voltage, the core recess amount, and the block layer recess amount of the source-side select transistor of the present embodiment. From FIG. 20, it can be seen that when the core recess amount is 50 nm, the larger the block layer recess amount, the lower the threshold voltage. A low threshold voltage leads to an increase in the driving power of the source-side select transistor.

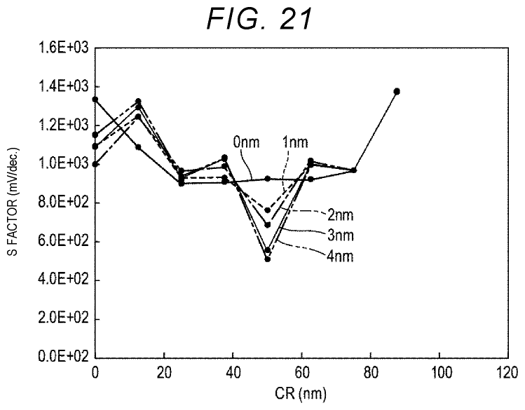

FIG. 21 is a diagram showing the S factor characteristics of the semiconductor memory device of the present embodiment, and more specifically, shows the relationship between the S factor, the core recess amount, and the block layer recess amount of the source-side select transistor of the present embodiment. From FIG. 21, it can be seen that when the core recess amount is 50 nm, the larger the block layer recess amount, the smaller the S factor. A small S factor leads to an increase in the driving power of the source-side select transistor.

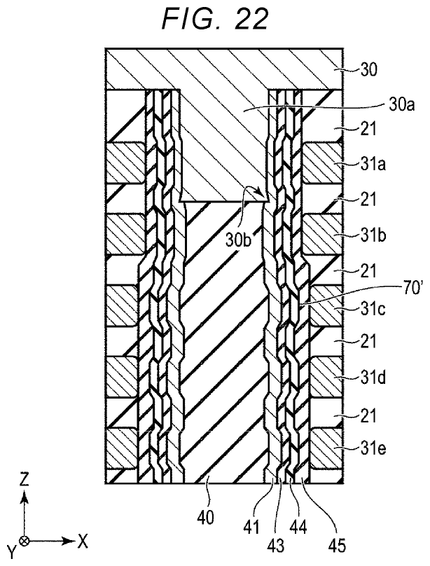

FIG. 22 is a sectional view showing a part of the semiconductor memory device of the modification example of the present embodiment, and corresponds to an enlarged sectional view of FIG. 5.

The semiconductor memory device of the modification example is different from the semiconductor memory device of the present embodiment in that the semiconductor layer 41, the tunnel insulating layer 43, and the charge storage layer 44 of the memory cell transistor include a protruding portion. In FIG. 22, the protruding portion of the charge storage layer 44 is denoted by the reference numeral 70′. However, for the sake of simplicity, the protruding portions of the semiconductor layer 41 and the tunnel insulating layer 43 are not denoted by the reference numerals. In the present embodiment, the protruding portion is located on the lateral side (X direction side) of the conductive layers 31c to 31e.

### Third Embodiment

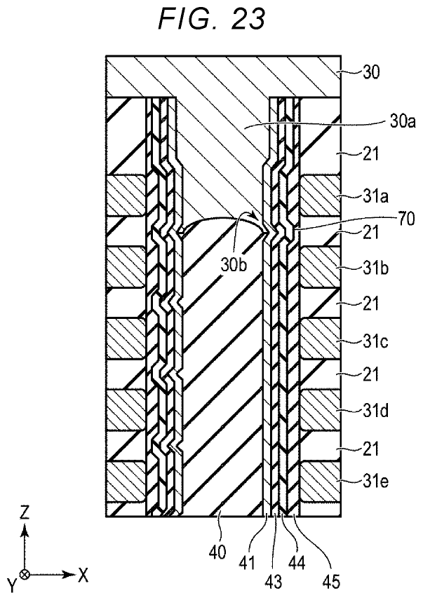

FIG. 23 is a sectional view showing a part of the semiconductor memory device according to the third embodiment, and corresponds to an enlarged sectional view of FIG. 5.

The present embodiment is a combination of the first embodiment and the second embodiment. That is, the semiconductor memory device of the present embodiment includes the pointed portion 30b and the protruding portion 70. The lower surface of the source line layer 30 and the upper surface of the core insulating layer 40 are curved surfaces as in the first embodiment. The protruding portion 70 is disposed adjacent to the pointed portion 30b in the X direction.

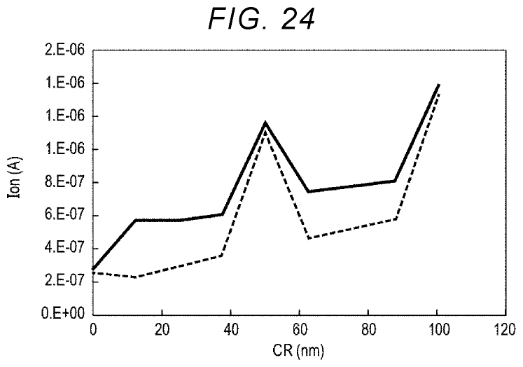

FIG. 24 is a diagram showing the on-current characteristics of the semiconductor memory device according to the first and third embodiments, and more specifically, is a diagram showing the relationship between the on-current and the core recess amount of the source-side select transistor of the first and third embodiments. The relationship between the on-current and the core recess amount of the semiconductor memory device of the present embodiment is indicated by a solid line, and the relationship between the on-current and the core recess amount of the semiconductor memory device of the first embodiment is indicated by a broken line.

From FIG. 24, it can be seen that when the core recess amount is 50 nm, that is, when the interface between the source line layer 30 and the core insulating layer 40 is located at the center between the conductive layer 31a and the conductive layer 31b in the Z direction, the on-current is more improved in the present embodiment. In addition, it can be seen that the on-current is higher in the present embodiment when the core recess amount is the same. This means that the dependence of the on-current on the core recess amount is lower in the present embodiment, that is, the variation in the on-current due to the difference in the core recess amount is small.

The reason why the on-current is more improved in the present embodiment is considered to be that the electric field of the corner portions (corner portions 71 and 72 in FIG. 15) of the conductive layers 31a and 32b is increased by using the protruding portion and the protruding portion in combination.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body in which a plurality of conductive layers and a plurality of insulating layers are alternately stacked in a first direction;
a columnar body provided in the stacked body and extending in the first direction; and
a source line layer containing a metal material, wherein
the columnar body includes a core insulating layer that extends in the first direction through the stacked body to be in contact with the source line layer, a semiconductor layer surrounding a side surface of the core insulating layer and in contact with the source line layer, and a memory layer surrounding a side surface of the semiconductor layer and in contact with the source line layer, and
a portion of the source line layer extends in the first direction to be provided in the stacked body, has a side surface in contact with a side surface of the semiconductor layer and an end face in the first direction in contact with the core insulating layer, and includes a pointed portion on the end face at an interface of the portion, the core insulating layer, and the semiconductor layer, wherein the end face of the portion and the side surface of the semiconductor layer form an acute angle at the pointed portion.

2. The semiconductor memory device according to claim 1,
wherein an end face of portion that is in contact with the core insulating layer has a curved surface.

3. The semiconductor memory device according to claim 2,
wherein the plurality of conductive layers include a plurality of first conductive layers connected to select transistors formed along the columnar body and a plurality of second conductive layers connected to memory cell transistors formed along the columnar body,
the plurality of first conductive layers are arranged between the source line layer and the plurality of second conductive layers in the first direction, and
the pointed portion is surrounded by one of the first conductive layers.

4. The semiconductor memory device according to claim 3, wherein the pointed portion is surrounded by one of the first conductive layers that is farthest away from the plurality of second conductive layers in the first direction.

5. The semiconductor memory device according to claim 4, wherein
the memory layer includes a tunnel insulating layer surrounding a side surface of the semiconductor layer, a charge storage layer surrounding a side surface of the tunnel insulating layer, and a block insulating layer surrounding a side surface of the charge storage layer, and
a thickness of the block insulating layer that surrounds the interface is smaller than a thickness of the block insulating layer that surrounds the neck region of the portion.

6. The semiconductor memory device according to claim 2,
wherein a surface of the core insulating layer in contact with the end face of the portion of the source line layer is a curved surface that is convex, and
the curved end face of the portion of the source line layer is concave.

7. A semiconductor memory device comprising:
a stacked body in which a plurality of conductive layers and a plurality of insulating layers are alternately stacked in a first direction;
a columnar body provided in the stacked body and extending in the first direction, the columnar body including a core insulating layer that extends in the first direction through the stacked body to be in contact with the source line layer, a semiconductor layer surrounding a side surface of the core insulating layer and in contact with the source line layer, and a memory layer surrounding a side surface of the semiconductor layer and in contact with the source line layer; and
a source line layer containing a metal material, wherein
a portion of the source line layer extends in the first direction to be provided in the stacked body and has a side surface in contact with a side surface of the semiconductor layer and an end face in the first direction in contact with the core insulating layer, and a diameter of the portion increases from a neck region of the portion to the end face of the portion.

8. The semiconductor memory device according to claim 7, wherein a diameter of the core insulating layer at an end face thereof in contact with the portion and the diameter of the end face of the portion are substantially the same.

9. The semiconductor memory device according to claim 8, wherein the diameter of the core insulating layer decreases from the end face thereof to a body region of the core insulating layer.

10. The semiconductor memory device according to claim 9, wherein the end face of the portion and the end face of the core insulating layer are each flat surfaces.

11. The semiconductor memory device according to claim 7, wherein the semiconductor layer at an interface of the portion and the core insulating layer protrudes outward towards the stacked body.

12. The semiconductor memory device according to claim 11, wherein
the memory layer includes a tunnel insulating layer surrounding a side surface of the semiconductor layer, a charge storage layer surrounding a side surface of the tunnel insulating layer, and a block insulating layer surrounding a side surface of the charge storage layer, and
a thickness of the block insulating layer that surrounds the interface is smaller than a thickness of the block insulating layer that surrounds the neck region of the portion.

13. The semiconductor memory device according to claim 7, wherein a diameter of the core insulating layer at an end face thereof in contact with the portion is less than the diameter of the end face of the portion.

14. The semiconductor memory device according to claim 13, wherein the end face of the portion and the end face of the core insulating layer are each flat surfaces.
